(19) United States
(12) Patent Application Publication
(10) Pub. No.: US 2026/0143830 A1
(43) Pub. Date: May 21, 2026

(54) SEMICONDUCTOR DETECTOR

(71) Applicant: KETEK GmbH Halbleiter-und Reinraumtechnik, Muenchen (DE)

(72) Inventors: Lothar Höllt, Bad Heilbrunn (DE); Sabrina Löbner, Germering (DE); Florian Dams, Regenstauf (DE); Florian Wagner, Muenchen (DE)

(21) Appl. No.: 18/949,608

(22) Filed: Nov. 15, 2024

(51) Int. Cl. H01L 31/117; G01T 1/24; H01L 31/0224

(52) U.S. Cl. CPC H10F 30/292; G01T 1/244; H10F 77/241

(57) ABSTRACT

In an embodiment a semiconductor detector includes a radiation entry side, a semiconductor body having an implantation region at a main surface facing the radiation entry side, the implantation region being configured to be contacted by a first electrical potential, and an insulator arranged between the radiation entry side and the semiconductor body, the insulator being configured to be contacted by a second electrical potential such that an inversion region is formed in the semiconductor body, wherein the inversion region is arranged in a recess formed in the implantation region and confined by the implantation region, and wherein an area fraction of the recess on a total area of the implantation region is between 0.01% and 4%, inclusive.

### TECHNICAL FIELD

The present disclosure relates to a semiconductor detector.

### SUMMARY

Embodiments provide a semiconductor detector that is in particular characterized by a high maximum radiation hardness.

According to at least one embodiment, the semiconductor detector comprises a radiation entry side. In particular, at the radiation entry side radiation to be detected enters the semiconductor detector during operation. The radiation to be detected is in particular electromagnetic radiation. For example, the semiconductor detector is configured to detect X-rays. Hence, the semiconductor detector may be an X-ray detector.

According to at least one embodiment, the semiconductor body comprises a semiconductor body. Preferably, the semiconductor body is doped with a first dopant of a first conductivity type. For example, the semiconductor body is based on a silicon material system and is n-doped.

During operation, charge carriers may be generated in the semiconductor body by the radiation entering the semiconductor detector via the radiation entry side. In the semiconductor body an electric field may be generated during operation, guiding the charge carriers to a read-out point. For example, the semiconductor detector may comprise a plurality of electrodes on a side facing away from the radiation entry side. These electrodes may be formed as concentrical rings around the read-out point, which preferably is an anode. By applying voltage to the ring electrodes, the electrical field, also referred to as a drift field, can be formed in the semiconductor body. At the read-out point, i.e. the anode, a detector signal may be detected as a current pulse emerging from the charge carriers collected and guided by the electrical drift field if radiation enters the semiconductor detector via the radiation entry side. The semiconductor detector may thus be a drift detector, in particular a silicon drift detector (SDD).

According to at least one embodiment, the semiconductor body comprises an implantation region at a main surface facing the radiation entry side. In particular, the implantation region is configured to be electrically contacted by a first electrical potential. In other words, during operation a first electrical potential can be applied to the implantation region.

In particular, in the implantation region of the semiconductor body may be doped oppositely to regions outside the implantation region, i.e. in bulk. For example, the semiconductor body is p-doped in the implantation region. A dopant for the implantation region may be boron, for example.

According to at least one embodiment, an insulator is arranged between the radiation entry side and the semiconductor body. In particular, the insulator is configured to be electrically contacted by a second electrical potential. In other words, during operation a second electrical potential can be applied to the insulator. Preferably, the second electrical potential is different from the first electrical potential.

For example, the insulator comprises at least one dielectric layer deposited on the side of the semiconductor body facing the radiation entry side.

In particular, by applying the first and second electrical potentials, an inversion region is formed in the semiconductor body. The inversion region may also be referred to as an inversion channel.

According to at least one embodiment, the inversion region is formed in a recess of the implantation region. In particular, the recess is confined by the implantation region. This means in particular that the implantation region comprises an opening, for example if seen from the radiation entry region. The inversion region preferably forms if during operation the first and second electrical potentials are applied to the implantation region and the insulator, respectively.

According to at least one embodiment, an area fraction of the recess on a total area of the implantation region is between 0.01% and 4%, inclusive. Preferably, the area fraction is between 0.1% and 2%, inclusive, or between 0.2% and 1%, inclusive. The area fraction is in particular determined by dividing an area of the recess by an area of the implantation region, in particular including the area recess. The area of the recess and the implantation region is, for example, determined on a side of the implantation region facing the radiation entry side.

For example, the recess in the implantation region has a lateral extent of between 1% and 20% of a lateral extent of the implantation region. Here and in the following, the lateral extent is in particular a maximal extent in a lateral direction. The lateral direction is in particular a direction parallel to the radiation entry side. If, for example, the implantation region has an elongated shape in lateral directions, the lateral extent is determined by a dimension along a lateral direction, which is its largest dimension.

By means of the inversion region a barrier can be formed in the semiconductor body, by which radiation hardness of the semiconductor body can be increased.

In at least one embodiment, the semiconductor detector comprises a radiation entry side and a semiconductor body. The semiconductor body comprises an implantation region at a main surface facing the radiation entry side, wherein the implantation region is configured to be contacted by a first electrical potential. Between the radiation entry side and the semiconductor body an insulator is arranged, which is configured to be contacted by a second electrical potential such that an inversion region is formed in the semiconductor body. The inversion region is arranged in a recess of the implantation region and is confined by the implantation region. An area fraction of the recess on a total area of the implantation region is between 0.01% and 4%, inclusive.

The semiconductor detector presented herein is based on the following technical considerations. In order to increase radiation hardness of the semiconductor detector and the semiconductor body of the semiconductor detector, a barrier is formed at a main surface of the semiconductor body facing the radiation entry side. For example, the maximal radiation exposure may be defined as a decrease of a carbon resolution (C-FWHM) of at most 4 eV. This means in particular, if the decrease in carbon resolution (C-FWHM) reaches 4 eV, the maximum radiation exposure is reached.

In particular, in applications with a high number of probes to be measured, such as energy dispersive X-ray spectroscopy (EDX) applications, semiconductor detectors are used with short peaking times around 100 ns or operated continuously. Thus, radiation exposure is comparably high. For example, a maximal radiation exposure of 10¹¹ cts/mm² can be reached after only a few months for commonly used semiconductor detectors such as conventional SDDs. Thus, a high radiation hardness is desired to increase the lifetime of the semiconductor detector. At the same time, it is desired to improve an initial carbon resolution (C-FWHM), i.e. the C-FWHM in the absence of a radiation exposure, in order to increase the maximum radiation exposure.

Common means to increase the radiation hardness include applying an electrical barrier at the radiation entry side, in particular at the main surface of the semiconductor body facing the radiation entry side. The barrier may be formed by an inversion region that is established by applying a potential difference to a dielectric passivation of the semiconductor body and an implantation region of the semiconductor body oppositely doped to the bulk region of the semiconductor body. Typically, the implantation region is kept as small as possible to avoid destruction of the crystal structure of the semiconductor body and maximize radiation sensitive areas of the semiconductor body. However, this increases an undesired leakage current in the semiconductor body.

Alternatively, the barrier may be formed by forming the implantation region continuously over a radiation window of the radiation entry side. This, however, destroys the crystal structure of the semiconductor body in this region and thus reduces the radiation sensitive area of the detector. Consequently, also the C-FWHM increases, decreasing the carbon resolution. Furthermore, by increasing the size of the implantation region, white-noise behavior of the semiconductor detector degrades.

The semiconductor detector described herein is based on the idea of forming a comparably large implantation region with a recess, in which the inversion region can be formed. Thus, the area of the inversion region is reduced and at the same time regions of the semiconductor body in which the bulk crystal structure is harmed or destroyed is decreased, compared to other commonly known measures to increase radiation hardness.

Advantageously, such a configuration improves white-noise behavior and decreases the damages to the crystal structure of the semiconductor body, compared to the case in which the implantation region does not comprise a recess. As a result, the C-FWHM at small peaking times as well as a small energy performance of the detector are significantly improved.

Furthermore, the leakage current at the radiation entry side, for example at the insulator, is reduced. As a result, higher potential differences up to at least −6 V can be applied, which improves the barrier, thus improving radiation hardness.

In particular, a pn-junction in the semiconductor body formed at an interface between the implantation region and the bulk semiconductor body is reduced, since in the recess no interface between implantation region and the semiconductor body may be present. As a result, an equivalent capacity related to the pn-junction can be reduced. Among other equivalent capacities, for example formed between the ring electrodes and the anode, the equivalent capacity corresponding to the implantation region contributes to a total (equivalent) capacity that determines a white noise amplitude.

In particular, an equivalent noise charge, ENC, is determined by the following equation:

$$E N {C}^{2} = {A}_{1} α \frac{2 {k}_{B} T}{{g}_{m}} \frac{{C}^{2}}{τ} + {A}_{2} 2 π {a}_{f} {C}^{2} + {A}_{3} {qI}_{l} τ ,$$

where A₁, A₂, A₃, α, 2k_{B}T, gₘ, a_{f} are constants assuming constant temperature, t is the peaking time, C is the total (equivalent) capacity, q is the charge of a current pulse of a detector signal, and I₁ is the leakage current. The first term in the sum of the equation above corresponds to the white noise, the second term corresponds to a 1/f noise and the last term corresponds to a parallel noise.

As can be seen from the equation above, the white noise behavior and the 1/f noise behavior can be improved with decreasing total capacity, in particular for small peaking times t. Furthermore, the parallel noise behavior can be improved by reducing the leakage current I₁.

Since the semiconductor detector described herein allows for a reduction of leakage current and a reduction of a capacity corresponding to the implantation region, the ENC can be reduced according to the equation above. As a result, an energy resolution can be increased, in particular for small peaking times. This improved energy resolution in particular leads to a reduced C-FWHM of the semiconductor detector.

In addition, a photon-sensible region of the semiconductor detector described herein, i.e. a region of the semiconductor detector in which the photons are detected, is closer to an external surface of the semiconductor detector at the radiation entry side, in particular compared to common detectors comprising a continuous implantation region covering the entire radiation entry side. Consequently, small-energy photons can be more efficiently detected. As a result, the small-energy performance of the semiconductor detector described herein is improved compared to common comparable detectors.

At the same time, radiation hardness of the implantation region comprising a recess described herein is comparable to cases in which the implantation regions do not comprise a recess. Thus, the above-mentioned improvements can be achieved without reducing radiation hardness. For example, a maximum radiation exposure of up to 2.5×10¹² cts/mm² are possible, thus increasing radiation hardness drastically compared to conventional comparable semiconductor detectors.

According to at least one embodiment, a potential difference between the second potential and the first potential has an absolute value of at least 4 V or preferably at least 6 V or further preferably at least 8 V during operation of the semiconductor detector. For example, the potential difference between the second potential and the first potential is determined by subtracting the first electrical potential from the second electrical potential, which yields a negative value. This means in particular that the potential difference can be between 0 V and −4 V, inclusive, between 0 V and −6 V, inclusive, or between 0 V and −8 V, inclusive. In particular, a lower boundary for a range of the differential voltage is at least −6 V. Hence, it is possible to operate the semiconductor detector described herein with a comparably large voltage difference. As a result, the barrier at the radiation entry side and consequently the radiation hardness can be improved.

According to at least one embodiment, the potential difference has an absolute value of at least 4 V or preferably at least 6 V or further preferably at least 8 V.

According to at least one embodiment of the semiconductor detector, the implantation region is a first circle, and the recess is a second circle, in a view onto the main surface of the semiconductor body. Preferably, the first circle of the implantation region and the second circle of the recess have a common center point. For example, the read-out point, i.e. the anode of the semiconductor detector, and the common center point overlap with each other in a direction perpendicular to the first main surface of the semiconductor body. This means in particular that, in a projection onto a common plane, i.e. a plane of the main surface, the center point of the first circle and the center point of the second circle each overlap with, or are essentially identical to the read-out point.

According to at least one embodiment, the radiation detector comprises a radiation entry window at the radiation entry side.

The radiation entry window is in particular a region of the radiation entry side through which radiation to be detected enters the semiconductor detector. For example, the detector is sensitive only to the radiation entering through the radiation entry window. This means in particular that only free charge carriers generated in the semiconductor body by radiation entering through the radiation entry window may be collected by the drift field and may generate a detector signal.

It is possible that regions of the radiation entry side outside the radiation entry window are shielded by a radiation shield or a housing of the semiconductor detector such that the radiation entry side is only exposed to radiation at the radiation entry window.

According to at least one embodiment of the semiconductor detector comprising a radiation entry window, the radiation window has a first contour in a view onto the radiation entry side. The implantation region has a second contour in a view onto the main surface of the semiconductor body. The first contour and the second contour are similar. It is possible that at least one of the first and second contours is an outer contour of the respective element.

By forming the implantation region with a similar contour as the radiation window, the barrier generated by the first and second electrical potentials and the implantation region during operation of the semiconductor detector can cover a majority or preferably all or essentially all of the radiation entry window. As a result, the radiation hardness of the semiconductor detector can be particularly high.

According to at least one embodiment of the semiconductor detector comprising a radiation entry window at the radiation entry side, an electrically conductive layer is arranged at the radiation entry side in a region of the radiation entry window. The electrically conductive layer is configured to apply the second potential to the insulator. For example, the electrically conductive layer is a contact layer for the second potential.

The electrically conductive layer preferably comprises at least one metal. For example, the electrically conductive layer is a metal layer. For example, the electrically conductive layer comprises at least one of the following metals: aluminum, copper, carbon.

For example, the electrically conductive layer comprises a thickness of between 1 nm and 5000 nm, inclusive. In particular, the thickness of the conductive layer is between 100 nm and 1000 nm. The thickness is in particular determined in a direction perpendicular to the radiation entry side.

According to at least one embodiment of the semiconductor layer comprising a radiation entry window and an electrically conductive layer at the radiation entry side, the electrically conductive layer covers at least 80% or preferably at least 90% or further preferably at least 95% of the radiation entry window in a view onto the radiation entry side. It is possible that the radiation entry window is completely or essentially completely covered by the conductive layer in a view onto the radiation entry side.

According to at least one embodiment of the semiconductor layer comprising a radiation entry window and an electrically conductive layer at the radiation entry side, the radiation entry window has the first contour, and the electrically conducive layer has a third contour. The first contour and the third contour preferably are similar. It is possible that at least one of the first and third contours is the outer contour of the respective element.

By forming the first and third contours similar, a particularly large area of the radiation entry window can be covered by the electrically conductive layer.

According to at least one embodiment, the insulator comprises at least one through-connection penetrating the insulator in a direction perpendicular to the radiation entry side. In particular, the through-connection is in electrical contact with the implantation region. The through-connection is in particular configured to apply the first potential to the implantation region. This means in particular that via the through-connection the first potential can be applied to the implantation region.

The through-connection comprises at least one metal such as aluminum and/or copper, for example.

In the case that the semiconductor detector comprises the electrically conductive layer for applying the second potential to the insulator, the through-connection is preferably separated, i.e. electrically and/or mechanically separated, from the electrically conductive layer. For example, a gap is provided between the through-connection and the electrically conductive layer. The gap in particular extends in the lateral direction. The gap can be filled with an electrically insulating material. Alternatively, the gap may be an air gap or preferably a vacuum gap.

It is possible that the through-connection completely surrounds the electrically conductive layer in lateral directions, in a view onto the radiation entry side.

According to at least one embodiment, the semiconductor body comprises an integrated voltage divider. The integrated voltage divider is in particular configured to generate the first potential from the second potential.

Thus, the semiconductor detector only needs one external terminal to apply the first and second potentials. As a result, electrically contacting the semiconductor detector is advantageously facilitated. Furthermore, a risk of voltage spikes of the differential voltage of the second potential and the first potential that may occur at a switch-on procedure of the semiconductor body and may damage or destroy the insulator, is significantly reduced.

By adjusting the voltage divider, the first potential can be accurately adjusted and generated from the second potential.

According to at least one embodiment of the semiconductor detector comprising an integrated voltage divider, the implantation region comprises an inner sub-region and an outer sub-region at least partially surrounding the inner sub-region. In particular the outer sub-region is configured to be contacted with the second electrical potential, and the inner sub-region is connected to the outer sub-region via a first resistance of the voltage divider. The first resistance is configured to generate the first potential from the second potential. For example, an electrical voltage drops at the first resistance such that the first potential is generated from the second potential.

In particular, the outer sub-region forms a frame around the inner sub-region at least partially or completely or essentially completely surrounding the inner sub-region laterally, for example in a view onto the main surface of the semiconductor body. The inner sub-region and outer sub-region are preferably separated from one another and only electrically connected via the first resistance.

For example, in a view onto the main surface of the semiconductor body, the inner sub-region and the outer sub-region are concentric rings.

According to at least one embodiment of the semiconductor detector comprising a voltage divider, a second resistance of the voltage divider is configured to electrically connect the inner sub-region to ground or a guard ring of the semiconductor detector.

Guard rings of the semiconductor detector are formed on a further main surface of the semiconductor body facing away from the radiation entry side. The guard rings are in particular configured to dismantle the electric drift field inside the semiconductor body, such that edge regions of the semiconductor body are free of the electrical drift field.

The guard rings preferably comprise at least one inner guard ring and at least one outer guard ring. The outer guard ring preferably surrounds the inner guard ring completely or essentially completely in view of the further main surface. Preferably, the second resistance is configured to connect the inner sub-region to the inner guard ring. Advantageously, the outer guard ring or outer guard rings can be formed as closed rings in view of the further main surface. This allows for an increased reduction of leakage currents, for example compared to a case in which the guard rings comprise cut-outs such that the second resistance connects the inner sub-region to the outer edge region of the semiconductor body, which may be on ground.

Alternatively, it is possible that the second resistance connects the inner sub-region to the outer edge region of the semiconductor body, which is preferably on ground. By such a configuration, the first voltage can advantageously be precisely controlled, in particular to a case where the second resistance is connected to the guard rings, since electrical potentials of the guard rings may be floating.

According to at least one embodiment, the first and second resistances are configured to generate a differential voltage between the second potential and the first potential of between 0 and −20V, inclusive.

According to a preferred embodiment, the inner sub-region is free of a current flow during operation. This means in particular, that the voltage divider is arranged such that the first potential is applied to the inner sub-region but no current flows in the inner sub-region. Advantageously, this allows to make the implantation current-free in the region of the inner sub-region. Thus, leakage current can be reduced.

According to at least one embodiment of the semiconductor detector comprising an integrated voltage divider, each of the first and second resistances is formed by a further implantation region of the semiconductor body. In the further implantation region, the semiconductor body is in particular doped such that these regions show a specific electrical resistance to match the formation of the first and second potentials.

According to at least one embodiment of the semiconductor detector comprising an integrated voltage divider, each of the first and second resistances is formed by a conductor integrated in the semiconductor body. A material and/or geometrical dimensions of the conductors are in particular adapted such that the conductors have a specific electrical resistance to match the formation of the first and second potentials. This means in particular that the first and/or second resistance is/are formed by a resistor.

It is also possible that each of the first and second resistances is partially formed by a further implantation region and partially formed by a conductor. It is further possible that the first resistance is formed by the conductor and the second resistance is formed by the further implantation region, or vice versa.

It is further possible that the first and/or second resistance is formed by a plurality of diodes that are operated in forward direction.

In particular, the first and/or second resistance are formed by any suitable electrical structure by which a defined resistance value for the first and second resistance can be achieved.

According to at least one embodiment of the semiconductor detector comprising an implantation region with an outer sub-region and an inner sub-region, the outer sub-region comprises a cut-out, wherein the first resistance and/or the second resistance is arranged at least partially in the cut-out. In the cut-out the semiconductor body may comprise the same material and doping as in the bulk region.

In particular, in the cut-out the electrical connection to ground and/or the guard rings is arranged. Alternatively or additionally, an electrical connection between the outer sub-region and the inner sub-region is arranged in the cut-out. In this case, the first resistance, which is in particular arranged in a conduction path between the outer sub-region and inner sub-region, is preferably arranged in the cut-out.

According to at least one embodiment of the semiconductor detector comprising an implantation region with an outer sub-region and an inner sub-region, the inner sub-region comprises a fourth contour and the outer sub-region comprises a fifth contour. In particular, the fourth and fifth contours are similar.

According to at least one embodiment of the semiconductor detector comprising an integrated voltage divider, the semiconductor detector comprises a metallization arranged at least partially at the radiation entry side, wherein the metallization penetrates the insulator in a direction perpendicular to the radiation entry side. In particular, the metallization electrically contacts the outer sub-region of the implantation region. Preferably, the second electrical potential can be applied to the outer sub-region of the implantation region via the metallization.

For example, the metallization defines a radiation entry window of the radiation entry side in a view onto the radiation entry side. This means in particular that a part of the radiation entry side covered by the metallization in a view onto the radiation entry side is the radiation entry window.

According to at least one embodiment of the semiconductor detector comprising a radiation entry window at the radiation entry side, the insulator has a greater thickness in regions outside the radiation window than in regions inside the radiation entry window. For example, in regions outside the radiation entry window, the insulator has a thickness between 10 nm and 500 nm, inclusive, preferably between 20 nm and 300 nm. For example, in regions inside the radiation entry window, the insulator has a thickness between 10 nm and 500 nm, inclusive, preferably between 20 nm and 300 nm. Here and in the following, a thickness of a layer or a structural element is in particular determined along a direction perpendicular to the radiation entry side.

According to at least one embodiment of the semiconductor detector, the insulator comprises a passivation layer on a side facing the radiation entry side. The passivation layer and the insulator outside the passivation layer may comprise different electrically insulating or dielectric materials. For example, the passivation layer comprises at least one nitride. A thickness of the passivation layer is between 1 nm and 200 nm, inclusive, preferably between 10 nm and 50 nm, inclusive.

According to at least one embodiment of the semiconductor detector comprising a passivation layer, the insulator comprises an oxide layer between the passivation layer and the semiconductor body. The oxide layer comprises silicon oxide or silicon dioxide, for example.

This means in particular that the insulator comprises at least two layers, i.e. the passivation layer and the oxide layer. The passivation layer and the oxide layer preferably comprise different materials. For example, the passivation layer comprises nitride and the oxide layer comprises oxide. During production of the semiconductor detector, the passivation layer is preferably formed after the oxide layer and further preferably after the implantation region. The oxide layer may be formed before the implantation region.

A thickness of the oxide layer is, for example, between 1 nm and 200 nm, inclusive, preferably between 10 nm and 50 nm, inclusive. For example, the oxide layer is thicker outside the radiation entry window than inside the radiation entry window. For example, a thickness of the oxide layer inside the radiation entry window is between 50 nm and 80 nm, inclusive. Outside the radiation entry window, the thickness of the oxide layer may be between 220 nm and 240 nm, inclusive.

Common comparable semiconductor detectors typically comprise only one insulating layer, which is typically an oxide layer. By forming the insulator with at least two insulating layers, i.e. the passivation layer and the oxide layer, as described herein, a leakage current can be reduced, since the passivation layer increases insulating properties of the insulator.

Due to the generation of the implantation region by implanting a dopant through the oxide layer, the oxide layer may be damaged. Thus, insulating properties of the oxide layer may decrease to the damage and a leakage current may increase. By applying the passivation layer, the insulating properties may be improved, and the leakage current can be decreased. Advantageously, the passivation layer is applied after forming the implantation region. Thus, the passivation layer is not damaged by implanting the dopant in the semiconductor body to form the implantation region.

According to at least one embodiment, the semiconductor body is doped with a first dopant of a first conductivity type, and the implantation region is doped with a second dopant of a second conductivity type opposite to the first conductivity type.

For example, the semiconductor body is n-doped and the implantation region is p-doped. A dopant in the implantation region is boron, for example.

According to at least one embodiment, the semiconductor detector is a silicon drift detector. The semiconductor body is preferably based on a silicon material system.

### BRIEF DESCRIPTION OF THE DRAWINGS

Further advantages and advantageous embodiments and further developments of the semiconductor detector described herein will become apparent from the following exemplary embodiments shown in connection with schematic drawings. Identical elements, elements of the same kind or elements having the same effect are provided with the same reference signs in the figures. The figures and the proportions of the elements shown in the figures are not to be regarded as true to scale. Rather, individual elements may be shown exaggeratedly large for better representability and/or for better comprehensibility.

FIG. 1 shows a schematic cross-sectional view of a semiconductor detector described here according to a first exemplary embodiment;

FIG. 2 shows a schematic representation of an implantation region of the semiconductor detector according to the first exemplary embodiment;

FIG. 3 shows a schematic representation of the semiconductor detector according to the first exemplary embodiment;

FIG. 4 shows a schematic cross-sectional view of a semiconductor detector described here according to a second exemplary embodiment;

FIG. 5 shows a schematic representation of an implantation region of the semiconductor detector according to the second exemplary embodiment;

FIGS. 6 and 7 illustrate different examples of contacting the implantation region of the second exemplary embodiment to ground; and

FIG. 8 shows a schematic representation of an implantation region of the semiconductor detector according to a third exemplary embodiment.

### DETAILED DESCRIPTION OF ILLUSTRATIVE EMBODIMENTS

FIG. 1 illustrates a semiconductor detector 1 described herein according to a first exemplary embodiment. The semiconductor detector 1 comprises a semiconductor body 2 based on a silicon material system. The semiconductor body 2 is n-doped.

On a main surface 20 of the semiconductor body 2 an insulator 4 is arranged. The insulator 4 is electrically insulating. The insulator 4 comprises an oxide layer 41 at the main surface 20 and a passivation layer 42 on a side of the oxide layer 41 facing away from the semiconductor body 2.

The oxide layer 41 comprises silicon dioxide, for example.

The passivation layer 42 comprises a nitride and has a thickness of between 10 nm and 50 nm. Here and in the following, a thickness of a layer or an element is measured perpendicular to the main surface 20.

At the main surface 20 the semiconductor body 2 comprises an implantation region 3. The implantation region 3 comprises a recess 30 completely penetrating the implantation region 3 in a direction perpendicular to the main surface 20. The implantation region 3 is p-doped, using boron as a dopant.

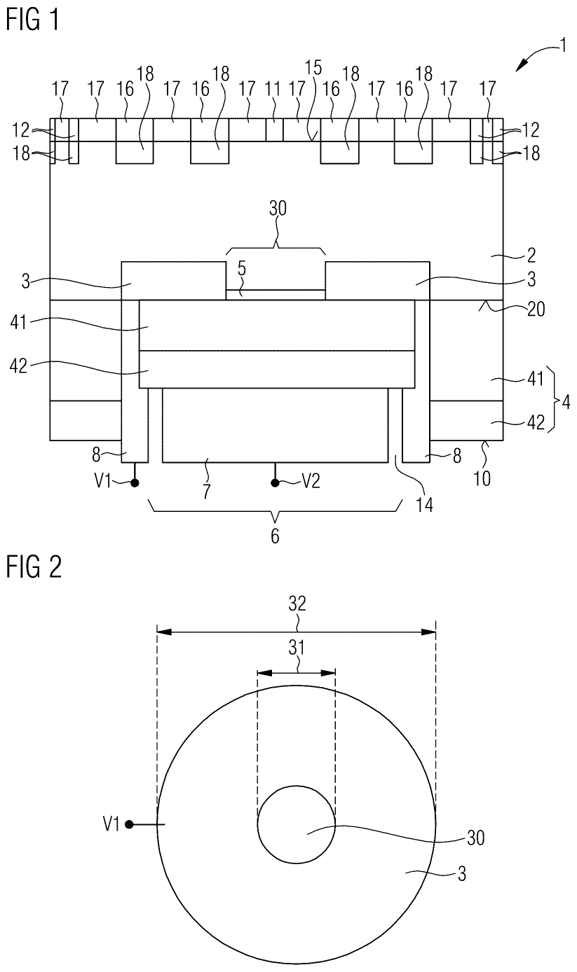

The implantation region 3 is circular in a view onto the main surface 20 (cf. FIG. 2). The recess 30 is also circular and has a common center point with the implantation region 3. A diameter 31 of the recess 30 is between 1% and 20% of a diameter 32 of the implantation region 3.

During operation of the semiconductor detector 1, radiation to be detected such as X-rays enter the semiconductor detector 1 through a radiation entry side 10. The radiation entry side 10 is a side of the insulator 4 facing away from the semiconductor body 2. At the radiation entry side 10 a radiation entry window 6 is defined. Radiation that enters the semiconductor detector 1 through the radiation entry window 6 can be detected by the semiconductor detector 1. Inside the radiation entry window 6 the insulator 4 has a smaller thickness than outside the radiation entry window 6.

For example, inside the radiation entry window 6 the oxide layer 41 has a thickness between 50 nm and 80 nm, inclusive, and outside the radiation entry window 6 the oxide layer 41 has a thickness between 220 nm and 240 nm, inclusive.

At the implantation region 3 a first electrical potential V1 can be applied. The first electrical potential V1 can be applied via a through-connection 8 penetrating the insulator 4 in a direction perpendicular to the radiation entry side 10. The through-connection 8 preferably comprises aluminum.

At the insulator 4 a second electrical potential V2 can be applied. The second electrical potential V2 can be applied via an electrically conductive layer 7. The electrically conductive layer 7 is preferably a metal layer and comprises aluminum.

The through-connection 8 laterally surrounds the conductive layer 7. This means in particular that the through-connection 8 forms a frame around the electrically conductive layer 7 in a view onto the radiation entry side 10. In particular, this frame defines the radiation entry window 6.

The through-connection 8 and the electrically conductive layer 7 are mechanically and electrically separated by a gap 14. The gap 14 is an air gap.

An outer contour of the radiation entry window 6 is similar to an outer contour of the implantation region 3 and the recess 30.

At a further main surface 15 of the semiconductor body 2, opposite the main surface 20, an anode 11 is arranged. In a projection onto the first main surface 20, the anode 11 overlaps with the center points of each of the implantation region 3, the recess 30 and the radiation entry window 6.

Furthermore, a plurality of ring electrodes 16 are arranged at the further main surface 15. The ring electrodes 16 are arranged concentrically around the anode 11. The ring electrodes 16 are separated from each other by a further insulator 17. At an interface to the ring electrodes 16 the semiconductor body 2 comprises doped regions 18 for electrically contacting the ring electrodes 16 to the semiconductor body 2. At an edge region 13 of the semiconductor detector 1, guard rings 12 are arranged at the further main surface 15 and the main surface 20.

During operation of the semiconductor detector 1, voltages are applied to the ring electrodes 16 such that an electrical drift field is generated in the semiconductor body 2. If radiation to be detected enters the semiconductor body 2 through the radiation entry window 6, charge carriers are generated in the semiconductor body 2. The charge carriers are guided to the anode 11 by the drift field, where a current pulse is generated as a detector signal from the charge carriers. At the edge region 13 the drift field is dismantled. For example, the guard rings 12 are on ground GND to make the semiconductor body 2 field-free in the edge region 13.

To increase radiation hardness of the semiconductor detector 1, a barrier is generated at the main surface 20 of the semiconductor body 2. The barrier is generated by applying the first electrical potential V1 and the second electrical potential V2, wherein an absolute value of the difference between the first and second electrical potentials is at least 6 V. By applying the potentials V1, V2, an inversion region 5 is generated in the recess 30. The inversion region 5 and the implantation region 3 act as the barrier.

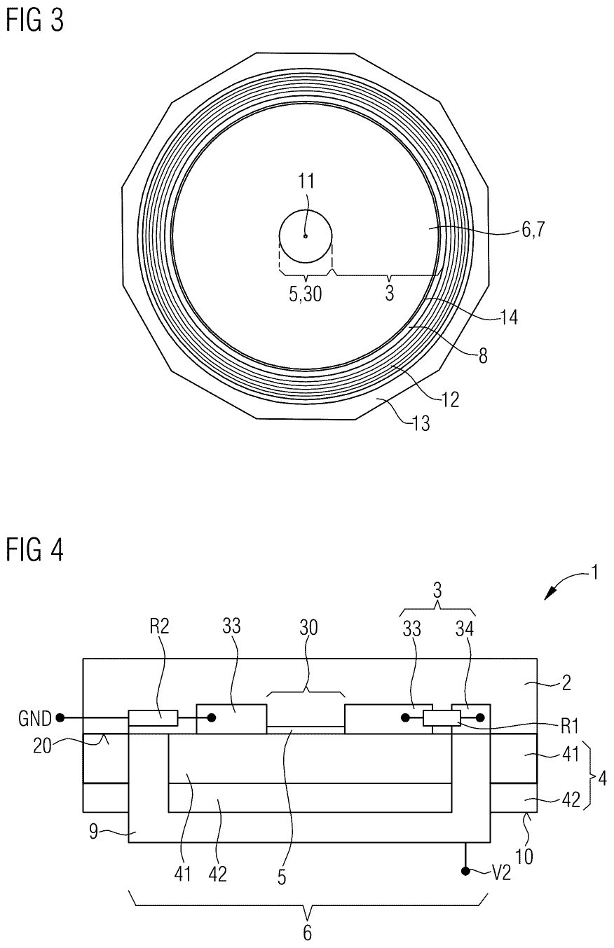

FIG. 3 shows a representation of the semiconductor detector 1 according to the first exemplary embodiment in a projection onto the radiation entry side 10. As can be seen from FIG. 3, the radiation entry window 6 is essentially completely formed by the electrically conductive layer 7 and surrounded by the through-connection 8. Furthermore, the anode 11 is located at the center of the implantation region 3 and the recess 30 in the projection of FIG. 3. Furthermore, in FIG. 3 the edge region 13 is shown. For the sake of a better illustration the ring electrodes 16 are omitted in FIG. 3.

FIG. 4 shows a sectional view of a semiconductor detector 1 according to a second exemplary embodiment. In contrast to the first exemplary embodiment, an inversion region 5 in the semiconductor detector 1 according to the second exemplary embodiment can be generated by externally applying only the second electrical potential V2. To achieve this, the semiconductor detector 1 comprises a voltage divider formed by a first resistance R1 and a second resistance R2.

The implantation region 3 comprises an inner sub-region 33 and an outer sub-region 34 partially surrounding the inner sub-region 33 (cf. FIG. 5). The inner sub-region 33 is connected to the outer sub-region 34 by the first resistance R1.

At the radiation entry side 10 the semiconductor detector 1 according to the second exemplary embodiment comprises a metallization 9 partially covering the radiation entry side 10. Regions of the radiation entry side 10 covered by the metallization 9 in particular define the radiation entry window 6. The metallization 9 comprises aluminum, for example.

The metallization 9 furthermore penetrates the insulator 4 completely and contacts the outer sub-region 34 of the implantation region 3. The outer sub-region 34 comprises a cut-out 35, in which at least partially the second resistance R2 is arranged. By the second resistance R2 the inner sub-region 33 is connected to ground GND. In FIG. 4 the sectional plane runs through the cut-out 35.

During operation of the semiconductor detector 1, the second electrical potential V2 is applied to the outer sub-region 34 via the metallization 9. By the voltage divider, i.e. by the first resistance R1 and second resistance R2, the first electrical potential V1 is generated at the inner sub-region 33. Thus, due to the voltage difference between the first electrical potential V1 and the second electrical potential V2, the inversion region 5 is formed. Thus, the barrier for increasing radiation hardness is generated.

The first and second resistances R1, R2 can each be formed by a doped region of the semiconductor body 2 and/or a conductor integrated in the semiconductor body 2.

In other aspects, the second exemplary embodiment comprises the same features and technical effects as the first exemplary embodiment. In particular, the semiconductor detector 1 according to the second exemplary embodiment comprises guard rings 12, ring electrodes 16 and an anode 11, which are omitted in FIG. 4 for better illustration.

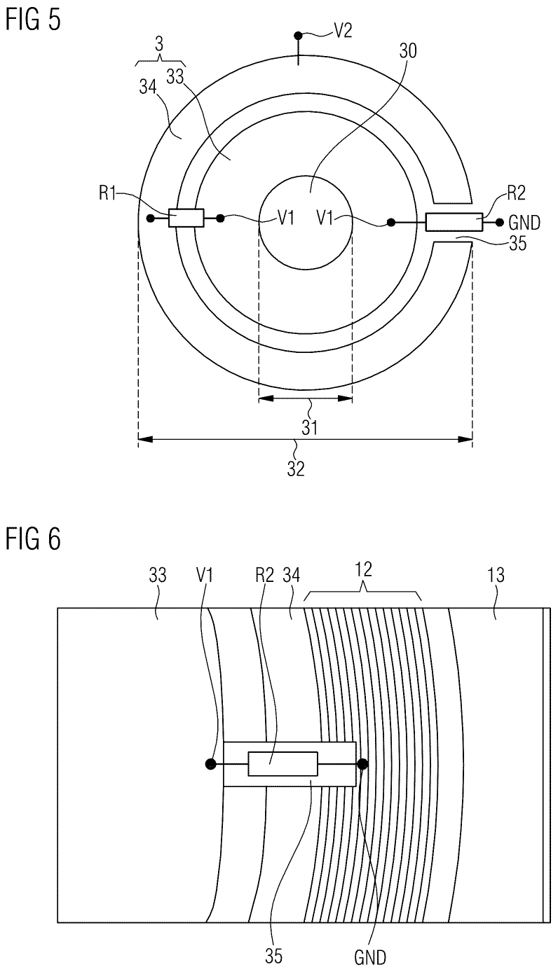

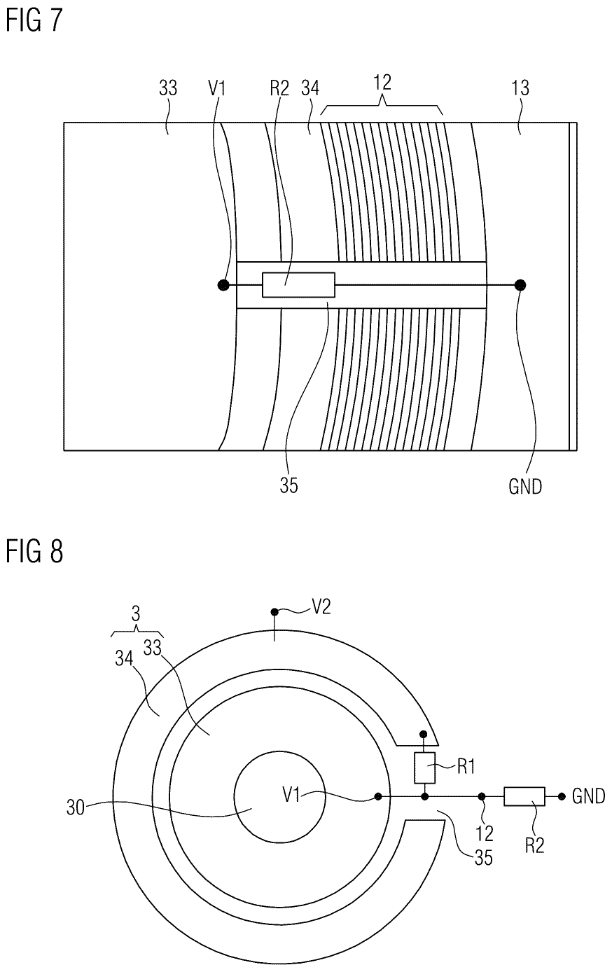

FIGS. 6 and 7 illustrate examples of contacting the inner sub-region 33 to ground GND via the second resistance R2.

According to the example of FIG. 6, the inner sub-region 33 is connected to one of the guard rings 12, which are preferably configured to dismantle the drift field in the semiconductor body 2 towards the edge region 13. The guard rings 12 preferably comprise at least one inner guard ring and at least one outer guard ring. The outer guard ring preferably surrounds the inner guard ring completely or essentially completely in view of the further main surface. Preferably, the second resistance R2 is configured to connect the inner sub-region 33 to the inner guard ring of the guard rings 12.

According to FIG. 7, the inner sub-region 33 is connected to the edge region 13 of the semiconductor body 2 via the second resistance R2. The edge region 13 is preferably field-free and on ground GND.

The third exemplary embodiment of the semiconductor 1 is different to the second exemplary embodiment in the voltage divider. In contrast to FIG. 5, the first resistance R1 is arranged in the cut-out 35 of the outer sub-region 34. Consequently, no current flows over the inner sub-region 33 during intended operation. At the same time, the first potential V1 can be applied to the inner sub-region 33 in a region of the cut-out 35.

The second resistance R2 can be arranged between the guard-rings 12 and ground GND at the edge region 13. It is also possible that the second resistance R2 is positioned as illustrated in FIGS. 6 and 7.

In other aspects, the third exemplary embodiment comprises the same features and technical effects as the second exemplary embodiment.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

What is claimed is:

1. A semiconductor detector comprising:
a radiation entry side;
a semiconductor body
comprising an implantation region at a main surface facing the radiation entry side, the implantation region being configured to be contacted by a first electrical potential; and
an insulator arranged between the radiation entry side and the semiconductor body, the insulator being configured to be contacted by a second electrical potential such that an inversion region is formed in the semiconductor body,
wherein the inversion region is arranged in a recess formed in the implantation region and confined by the implantation region, and
wherein an area fraction of the recess on a total area of the implantation region is between 0.01% and 4%, inclusive.

2. The semiconductor detector according to claim 1,
wherein the semiconductor detector is configured to have a potential difference between the second potential and the first potential, the potential difference having an absolute value of at least 6 V.

3. The semiconductor detector according to claim 1,
wherein, in a view onto the main surface of the semiconductor body, the implantation region is a first circle and the recess is a second circle, the implantation region and the recess having a common center point.

4. The semiconductor detector according to claim 1, further comprising a radiation entry window at the radiation entry side,
wherein the radiation entry window has a first contour in a view onto the radiation entry side,
wherein the implantation region has a second contour in a view onto the main surface of the semiconductor body, and
wherein the first contour and the second contour are similar.

5. The semiconductor detector according to claim 1, further comprising:
a radiation entry window at the radiation entry side; and
an electrically conductive layer arranged at the radiation entry side in a region of the radiation entry window, and
wherein the electrically conductive layer is configured to apply the second potential to the insulator.

6. The semiconductor detector according to claim 5,
wherein the electrically conductive layer covers at least 90% of the radiation entry window in a view onto the radiation entry side.

7. The semiconductor detector according to claim 1,
wherein the insulator comprises at least one through-connection penetrating the insulator in a direction perpendicular to the radiation entry side, and
wherein the through-connection is in electrical contact with the implantation region.

8. The semiconductor detector according to claim 1, wherein the semiconductor body comprises an integrated voltage divider configured to generate the first potential from the second potential.

9. The semiconductor detector according to claim 8,
wherein the implantation region comprises an inner sub-region and an outer sub-region at least partially laterally surrounding the inner sub-region,
wherein the outer sub-region is configured to be contacted with the second electrical potential,
wherein the inner sub-region is connected to the outer sub-region via a first resistance of the voltage divider, and
wherein the first resistance is configured to generate the first potential from the second potential.

10. The semiconductor detector according to claim 9,
wherein a second resistance of the voltage divider is configured to electrically connect the inner sub-region to ground or to a guard ring of the semiconductor detector, and
wherein the first and second resistances are configured to generate a differential voltage between the second potential and the first potential of between 0 and −20 V, inclusive.

11. The semiconductor detector according to claim 9, wherein the inner sub-region is configured to be free of a current flow.

12. The semiconductor detector according to claim 10, wherein the first and second resistances are each formed by a further implantation region of the semiconductor body.

13. The semiconductor detector according to claim 10, wherein the first and second resistances are each formed by a conductor integrated in the semiconductor body.

14. The semiconductor detector according to claim 10,
wherein the outer sub-region comprises a cut-out, and
wherein the first resistance and/or the second resistance is arranged at least partially in the cut-out.

15. The semiconductor detector according to claim 9,
wherein the inner sub-region comprises a fourth contour and the outer sub-region comprises a fifth contour, and
wherein the fourth and fifth contours are similar.

16. The semiconductor detector according to claim 9, further comprising a metallization arranged at least partially at the radiation entry side, wherein the metallization penetrates the insulator in a direction perpendicular to the radiation entry side, and
wherein the metallization electrically contacts the outer sub-region of the implantation region.

17. The semiconductor detector according to claim 1, further comprising a radiation entry window at the radiation entry side,
wherein the insulator has a greater thickness in regions outside the radiation entry window than in regions inside the radiation entry window.

18. The semiconductor detector according to claim 1,
wherein the insulator comprises a passivation layer on a side facing the radiation entry side, and
wherein the passivation layer and the insulator outside the passivation layer comprise different electrically insulating materials.

19. The semiconductor detector according to claim 18,
wherein the insulator comprises an oxide layer between the passivation layer and the semiconductor body.

20. The semiconductor detector according to claim 1,
wherein the semiconductor body is doped with a first dopant of a first conductivity type, and
wherein the implantation region is doped with a second dopant of a second conductivity type opposite to the first conductivity type.
